(19) United States
(12) Patent Application Publication
(10) Pub. No.: US 2026/0165117 A1
(43) Pub. Date: Jun. 11, 2026

(54) SEMICONDUCTOR DEVICE

(71) Applicant: Renesas Electronics Corporation, Tokyo (JP)

(72) Inventors: Naohito SUZUMURA, Tokyo (JP); Hideaki TSUCHIYA, Tokyo (JP)

(21) Appl. No.: 19/371,022

(22) Filed: Oct. 28, 2025

(30) Foreign Application Priority Data
Dec. 5, 2024 (JP) 2024-212196

(51) Int. Cl. H01L 23/525; H01L 23/522

(52) U.S. Cl. CPC H10W 20/493; H10W 20/42

(57) ABSTRACT

It can blow an electric fuse with a small blowing current. A metal film is connected to a first wiring through a first via, and is connected to a second wiring through a second via. A disconnect transistor is coupled to the second wiring. An area of a contact surface, which is in contact with the metal film, of the first via is smaller than an area of a contact surface, which is in contact with the metal film, of the second via.

### CROSS-REFERENCE TO RELATED APPLICATION

The disclosure of Japanese Patent Application No. 2024-212196 filed on Dec. 5, 2024, including the specification, drawings and abstract is incorporated herein by reference in its entirety.

### BACKGROUND

The present disclosure relates to a semiconductor device, and relates to, for example, a semiconductor device including an electric fuse.

There is disclosed technique listed below.
[Patent Document 1] Japanese Unexamined Patent Application Publication No. 2023-36246

As a related art, the Patent Document t 1 discloses a semiconductor device including an electric fuse that is disconnected by a flow of an electric current. The electric fuse includes an electric fuse element. The electric fuse element includes silicon chromium or silicon metal such as silicon chromium doped with carbon. Alternatively, the electric fuse element includes a metal film made of nickel chromium. A first end of the electric fuse element is coupled to a first wiring through a via conductive layer. A second end of the electric fuse element is connected to a second wiring through a via conductive layer. A width of a center part of the electric fuse element is smaller than a width of each of both ends of the electric fuse element. By a flow of a blowing current in the electric fuse element, the blowing current is concentrated on the center part of the electric fuse element, and the center part of the electric fuse element is blown.

### SUMMARY

A thickness of a thin-film resistor made of silicon chromium or others is smaller than a thickness of a resistor made of polysilicon or metal. A blowing resistance of the thin-film resistor made of silicon chromium or others is lower than a blowing resistance of the resistor made of polysilicon or metal. Therefore, it is conceivable to apply the thin-film resistor made of silicon chromium or others to the electric fuse. Meanwhile, in a semiconductor device in which its cost is to be reduced by downsizing of a chip size, it is desirable to decrease an area of the electric fuse. The element downsizing needs shortening of the thin-film resistor included in the electric fuse. However, if the thin-film resistor is shortened, heat dissipation from the thin-film resistor is easily caused, and the blowing current is increased. If the blowing current is increased, it is difficult to downsize a transistor used for controlling the blowing current.

Other objects and novel characteristics will be apparent from the description of the present specification and the accompanying drawings.

According to one embodiment, a semiconductor device is provided. The semiconductor device includes a metal film connected to a first wiring through a first via and a second wiring through a second via. An area of a contact surface, which is in contact with the metal film, of the first via is smaller than an area of a contact surface, which is in contact with the metal film, of the second via.

In the semiconductor device according to the one embodiment, a blowing current of an electric fuse can be decreased.

### BRIEF DESCRIPTIONS OF THE DRAWINGS

FIG. 1 is a plan view showing an electric fuse included in a semiconductor device according to a first embodiment.

FIG. 2 is a cross-sectional view of the semiconductor device, taken along a line A-A of FIG. 1.

FIG. 3 is a circuit diagram showing an equivalent circuit of the electric fuse.

FIG. 4 is a diagram showing temperature distribution of vicinity of a connection part between a metal film and a via.

FIG. 5 is a diagram showing temperature distribution of vicinity of the connection part between the metal film and the via.

FIG. 6 is a block diagram showing a semiconductor device to which the electric fuse is applied.

FIG. 7 is a diagram schematically showing a configuration of the semiconductor device.

FIG. 8 is a graph showing relation between an electric current and an applied voltage on the electric fuse.

FIG. 9 is a graph showing relation between an electric current and an area of the via.

FIG. 10 is a plan view showing an electric fuse included in a semiconductor device according to a second embodiment.

FIG. 11 is a circuit diagram showing an equivalent circuit of electric fuses.

FIG. 12 is a cross-sectional view showing a semiconductor device according to a third embodiment.

### DETAILED DESCRIPTION

Embodiments to which means for solving the problem will be described in detail below with reference to the drawings. In order to make the description clear, the following description and drawings will be appropriately omitted and simplified. The same components in each drawing are denoted by the same reference symbols, and the repetitive description thereof is omitted if needed.

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, numerical values, amount, range, and the like), the number of the elements is not limited to a specific number unless otherwise stated or except the case where the number is apparently limited to a specific number in principle. The number larger or smaller than the specified number is also applicable.

Further, in the embodiments described below, the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the number or the like (including the number, the numerical value, the amount and the range).

### First Embodiment

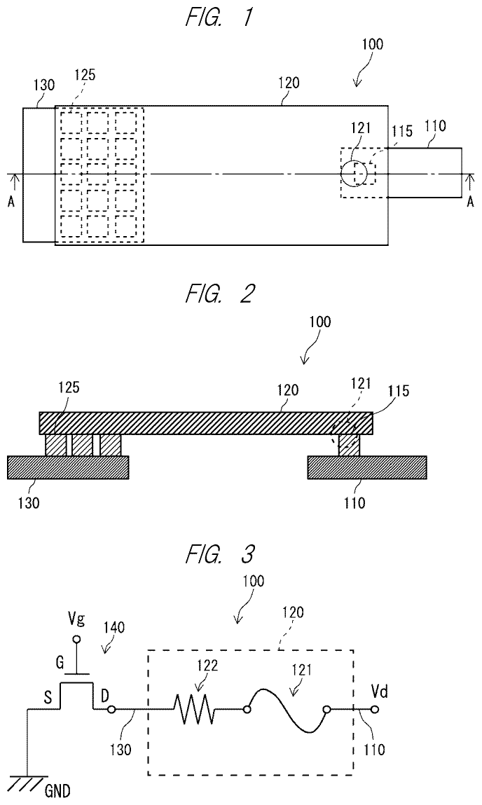

FIG. 1 is a plan view showing an electric fuse included in a semiconductor device according to a first embodiment. FIG. 2 is a cross-sectional view showing a A-A cross section of FIG. 1. An electric fuse 100 includes a wiring 110, a metal film 120, and a wiring 130. In the electric fuse 100, conduction between the wiring 110 and the wiring 130 is disconnected when the electric current flows in the metal film 120. One end of the metal film 120 is electrically connected to the wiring 110. The other end of the metal film 120 is electrically connected to the wiring 130. The wiring 110 is also referred to as first wiring. The wiring 130 is also referred to as second wiring.

As shown in FIG. 2, the semiconductor device in which the electric fuse 100 is formed includes a plurality of layers. In the electric fuse 100, the metal film 120 is positioned to be upper than the wiring 110 and the wiring 130. The metal film 120 is made of, for example, silicon metal or titanium nitride. The silicon metal includes, for example, silicon chromium or silicon chromium doped with carbon. The metal film 120 may be made of nickel chromium. The metal film 120 has a thickness of, for example, about several nanometers (nm). A resistance of the metal film 120 is set to be higher than resistances of the wiring 110 and the wiring 130. The metal film 120 is also referred to as thin-film resistor. As different from FIG. 2, in the electric fuse 100, the metal film 120 may be positioned to be lower than the wiring 110 and the wiring 130.

The metal film 120 is connected to the wiring 110 through a via 115. Also, the metal film 120 is connected to the wiring 130 through a plurality of vias 125. The metal film 120 is formed into, for example, a rectangular shape in plan view. A width of the metal film 120 is constant in a direction perpendicular to a direction extending from one end to the other end of the metal film 120. Each of the wiring 110 and the wiring 130 is made of a conductor having a higher conductivity than that of the metal film 120. Each of the wiring 110 and the wiring 130 is made of, for example, metal such as aluminum, copper and aluminum copper. Each of the via 115 and the vias 125 is made of, for example, tungsten. A metal such as barrier metal may be formed at a boundary between the metal film 120 and the via 115 and a boundary between the metal film 120 and the vias 125. The via 115 is also referred to as first via. The plurality of vias 125 are also referred to as second via.

In an example of FIG. 1, the wiring 110 is connected to the metal film 120 through single via 115. On the other hand, the wiring 130 is connected to the metal film 120 through the plurality of vias 125. In the example of FIG. 1, the number of the plurality of vias 125 is, for example, 15. For example, if an area of one via is the same among the plurality of vias, contact areas between the vias and the metal film 120 are proportional to the number of vias. In the first embodiment, an area of a contact surface, which is in contact with the metal film 120, of the via 115 is smaller than a total area of the contact surfaces, which are in contact with the metal film, of the plurality of vias 125. Note that the number of the vias 115 is not limited to one, and a plurality of vias 115 may be formed. In this case, the number of the plurality of vias 115 is smaller than the number of the plurality of vias 125.

The wiring 130 is coupled to a disconnect transistor that is a switching element. As the disconnect transistor, for example, a metal oxide semiconductor (MOS) transistor is used. The disconnect transistor controls the blowing current of the electric fuse. At the time of the disconnection of the fuse, the disconnect transistor is turned ON, thereby making a flow of the blowing current from the wiring 110 to the metal film 120. A part of the metal film 120, the part being connected to the via 115, is blown by the heat generated by the blowing current. The part of the metal film 120, the part being connected to the via 115, configures a blowing portion 121.

FIG. 3 is a circuit diagram showing an equivalent circuit of the electric fuse 100. The metal film 120 includes the blowing portion 121 and a resistor portion 122. The wiring 110 is coupled to, for example, a power supply voltage Vd. The wiring 130 is coupled to the disconnect transistor 140. For example, a source of the disconnect transistor 140 is coupled to a ground voltage, and a drain thereof is coupled to the wiring 130. A gate of the disconnect transistor 140 is coupled to a terminal to which a control signal Vg for controlling the disconnection of the fuse is input. When the electric fuse 100 is to be disconnected, the disconnect transistor 140 is turned ON by the control signal Vg.

When the disconnect transistor 140 is turned ON, the power supply voltage Vd is applied to the metal film 120 through the wiring 110, and the blowing current is supplied from the wiring 110. The blowing current flows to the wiring 130 through the blowing portion 121 and the resistor portion 122. More specifically, the blowing current flows from the wiring 110 to the metal film 120 through the via 115, and flows to the wiring 130 through the plurality of vias 125. By the flow of the blowing current from the wiring 110 to the metal film 120, the blowing current particularly concentrates on the via 115, and the part of the metal film 120, the part being connected to the via 115, is heated by Joule heat. The part of the metal film 120, the part being connected to the via 115, is blown when exceeding certain temperature.

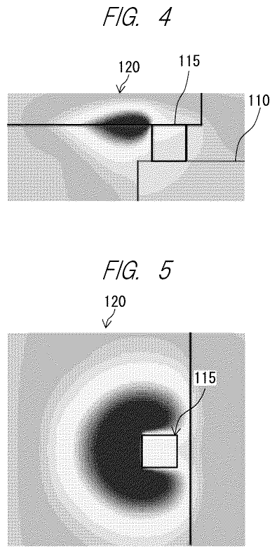

FIGS. 4 and 5 are diagrams each showing temperature distribution of vicinity of the connection part between the metal film 120 and the via 115. FIG. 4 shows a cross-sectional view of the vicinity of the connection part between the metal film 120 and the via 115. FIG. 5 shows a plan view of the vicinity of the connection part between the metal film 120 and the via 115. FIGS. 4 and 5 show that a part with a relatively low luminance, that is a nearly black part, has a higher temperature than that of a nearly white part. As shown in FIGS. 4 and 5, by the flow of the blowing current from the wiring 110 to the metal film 120 through the via 115, the part of the metal film 120, the part being connected to the via 115, is heated by Joule heat. The part of the metal film 120, the part being connected to the via 115, is blown when exceeding certain temperature.

In the first embodiment, the metal film 120 is connected to the wiring 130 through the plurality of vias 125, and a current flowing in a part of the metal film 120, the part being connected to each via 125, is smaller than a current flowing in the part of the metal film 120, the part being connected to the via 115. Therefore, the generated heat in the part of the metal film 120, the part being connected to each via 125, is lower than the generated heat in the part of the metal film 120, the part being connected to the via 115, and therefore, the part of the metal film 120, the part being connected to each via 125, is not blown. Also, in the first embodiment, a width of the wiring 110 is formed to be smaller than a width of the wiring 130. In this case, it is more difficult to release the generated heat in the part of the metal film 120, the part being connected to the via 115, than a case in which the widths of the wirings 110 and 130 are the same as each other. Therefore, the part of the metal film 120, the part being connected to the via 115, can be intendedly blown by the flow of the blowing current to the metal film 120.

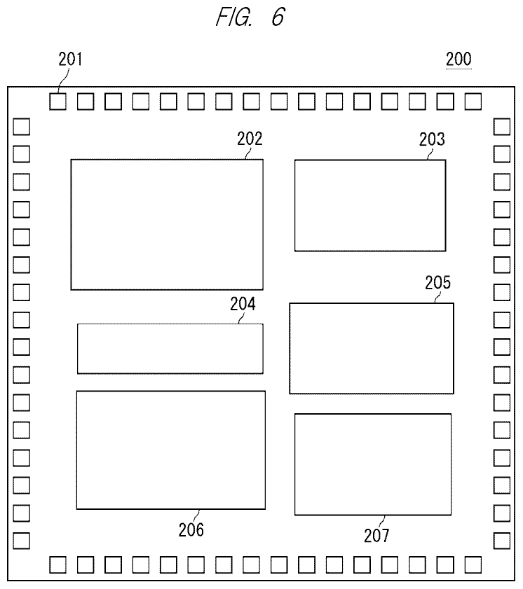

FIG. 6 is a block diagram showing a semiconductor device to which the electric fuse 100 is applied. A semiconductor device 200 is, for example, a microcomputer. The semiconductor device 200 is formed in, for example, a chip state. The semiconductor device 200 includes a plurality of electric elements arranged on an upper surface of a semiconductor substrate and above the semiconductor substrate. In an example of FIG. 6, the semiconductor device 200 includes a random access memory (RAM) region 202, a power supply circuit region 203, a central processing unit (CPU) region 204, peripheral circuit regions 205 and 206, and a redundancy circuit region 207. The semiconductor device 200 further includes a plurality of pad electrodes 201 around a semiconductor chip. Each of the plurality of pad electrodes 201 is electrically connected to an electric element arranged in the semiconductor device 200.

The redundancy circuit region 207 includes a backup redundancy circuit. The backup redundancy circuit has the same function as a specific circuit having a predetermined function. The electric fuse 100 to be blown and removed is arranged in the semiconductor device 200 in order to replace the specific circuit with the redundancy circuit.

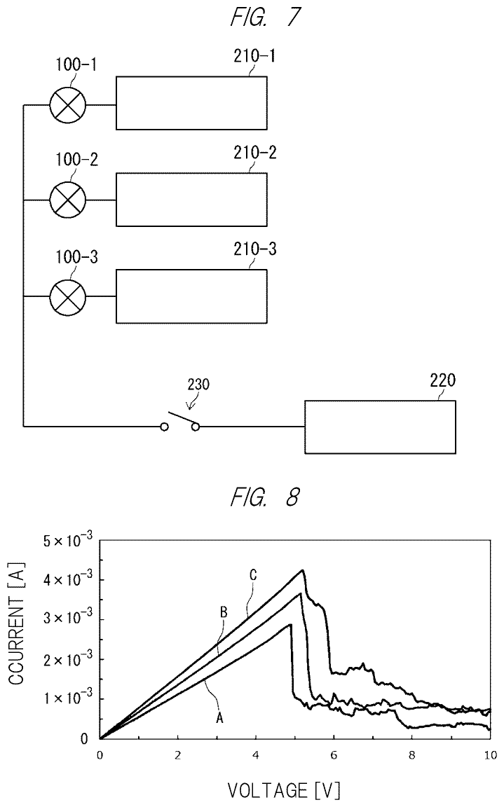

FIG. 7 is a diagram schematically showing a configuration of the semiconductor device 200. The semiconductor device 200 includes a plurality of functional blocks 210-1 to 210-3 and a redundancy block. Each of the plurality of functional blocks 210-1 1 to 210-3 is the specific circuit for achieving the predetermined function. The specific circuit is made of, for example, a plurality of memory cells in the RAM region 202. The redundancy block 220 is the backup redundancy circuit, and has the same function as the specific function.

The electric fuses 100-1 to 100-3 are disconnected for inactivating the plurality of functional blocks 210-1 to 210-3, respectively. For example, if failure is detected in any of the plurality of functional blocks 210-1 to 210-3 in the test for the semiconductor device 200, the blowing current is supplied to the corresponding electric fuse to disconnect the electric fuse. For example, if the failure is detected in the functional block 210-1, the blowing current is supplied to the electric fuse 100-1, and the state of the electric fuse 100-1 changes from the conduction state to the non-conduction state. In this manner, the functional block 210-1 is separated from the functional block 210-2 and the functional block 210-3.

Normally, the switch 230 is turned OFF, and the redundancy block 220 in the semiconductor device 200 is separated from the plurality of functional blocks 210-1 to 210-3. If the failure is detected in any of the functional blocks, the switch 230 is controlled to be turned ON, and the redundancy block 220 is connected to the functional block. For example, if the failure is detected in the functional block 210-1, the redundancy block 220 provides a predetermined function, instead of the functional block 210-1 being separated by using the electric fuse 100-1.

FIG. 8 is graphs each showing a relation between an electric current and an applied voltage on the electric fuse 100. In each graph shown in FIG. 8, a horizontal axis indicates the applied voltage, and a vertical axis indicates the electric current. The present inventors have prepared some prototypes that are different from one another in the number of vias 115 connected to the metal film 120 having predetermined length and width, and have examined the relation between the electric current and the applied voltage. A graph “A” indicates a relation between an electric current flowing in the metal film 120 and an applied voltage in a case in which the number of vias 115 is one. A graph “B” indicates a relation between an electric current flowing in the metal film 120 and an applied voltage in a case in which the number of vias 115 is two. A graph “C” indicates a relation between an electric current flowing in the metal film 120 and an applied voltage in a case in which the number of vias 115 is three.

In a case of increase in the voltage applied on the metal film 120, the electric current flowing in the metal film 120 is increased by the increase in the voltage. The increase in the electric current to some extent blows the part of the metal film 120, the part being connected to the via 115, and the electric current is decreased. The maximum value of the electric current at the time of the blowing is equivalent to the blowing current. The electric current concentrates on the small area when the number of vias 115 is small, thereby decreasing the area of the contact surface between the metal film 120 and the via 115. Therefore, as shown in the graphs A to C, the smaller the number of vias 115 is, in other words, the smaller the area of the contact surface is, the smaller the blowing current can be.

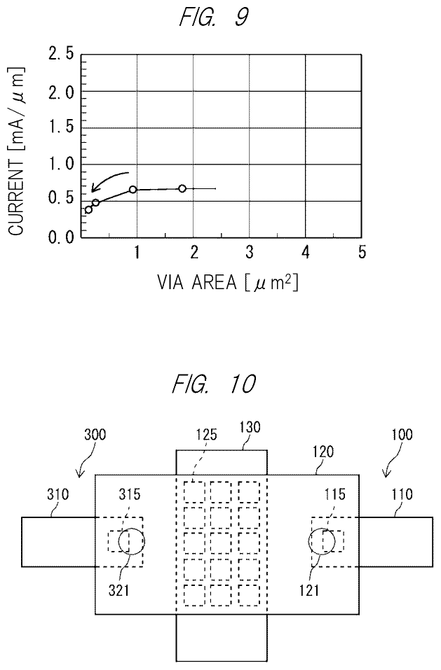

FIG. 9 is a graph showing a relation between the electric current and the area of the via 115. In the graph shown in FIG. 9, a horizontal axis indicates the area of the via 115, and a vertical axis indicates the electric current flowing in the metal film 120. A length of the metal film 120 in a direction of the electric current flow from the wiring 110 to the wiring 130 is set to be 25 μm. A width of the metal film 120 is set to be 10 μm. A plain shape of the via 115 is set to be a square shape or a rectangular shape. When a certain voltage or larger is applied, an electric current based on a resistance component flows in the metal film 120. As shown in FIG. 9, if an area of the via 115 is larger than 1 [μm], the electric current flowing in the metal film 120 is a constant electric current not depending on the area of the via 115. If an area of the via 115 is smaller than 1 [μm], the electric current concentrates on the via 115, thereby blowing the vicinity of the via 115, and the electric current flowing in the metal film 120 is made smaller than the electric current based on the resistance component.

### Effects

In the first embodiment, the metal film 120 is connected to the wiring 110 through the via 115, and is connected to the wiring 130 through the via 125. The wiring 130 is coupled to a disconnect transistor 140 for controlling disconnection of the electric fuse 100. In the first embodiment, the area of the contact surface between the metal film 120 and the via 115 is smaller than the area of the contact surface between the metal film 120 and the via 125. In this manner, the electric current can concentrate on the part of the metal film 120, the part being connected to the via 115, and thus, the part of the metal film 120, the part being connected to the via 115, can be easily blown.

In the Patent Document 1, the electric fuse element is made of a film such as a silicon metal film, and a width of a center of the electric fuse element in the longitudinal direction is smaller than a width of each of both ends of the electric fuse element. In this case, since the electric current concentrates on the center, the center of the electric fuse element is blown. On the other hand, in the first embodiment, since the part of the metal film 120, the part being connected to the via 115, is blown, the function of the fuse is provided. In the first embodiment, the part of the metal film 120, the part being connected to the via 115, can be blown by a lower electric current than that in a case in which the center of the electric fuse element is blown. Also, in the first embodiment, the part of the metal film 120, the part being connected to the via 115, can be blown even when the element resistance is low, in other words, even when the metal film 120 is short. Therefore, the electric fuse 100 can be downsized.

In the electric fuse 100, a case of use of a polysilicon film instead of the metal film 120 that is the thin film resistor will be discussed. Generally, it is difficult to thin the polysilicon film. A blowing resistance of metal used for the wiring 110 is lower than a blowing resistance of polysilicon, and therefore, the blowing is easily caused between the via and the wiring 110. However, a shape is designed such that a connection portion between the polysilicon film and the via is blown. When the polysilicon film is used for the electric fuse, either the polysilicon or the metal may be possibly blown, and therefore, there is a possibility of failure to break the electric fuse at a desirable position. Therefore, when the polysilicon film is used, the disconnect position is inconstant, and the disconnect current may vary. When the metal film 120 made of silicon chromium or the like is used, the metal film 120 is easier to be blown than the metal, and therefore, the above-described failure does not occur.

### Working Examples

In order to confirm effects of the first embodiment, the present inventors have made the examination for measuring the blowing current of the electric fuse and the power at the time of the blowing in some patterns. The following table 1 shows the examination results.

| | | | | | Blowing | |
|---|---|---|---|---|---|---|
| | Element | L | W | Resistance | current | Power |
| No. | structure | (μm) | (μm) | (Ω) | (mA) | (mW) |
| 1 | N = 1 | 0.92 | 20 | 520 | 2.8 | 6.7 |
| 2 | N = 3 | 0.92 | 20 | 600 | 3.7 | 8.2 |
| 3 | N = 3 × 20 | 25 | 10 | 3500 | 6.4 | 143.4 |
| 4 | N = 3 × 10 | 5 | 5 | 1400 | 5 | 35 |
| 5 | N = 3 | 10 | 0.44 | 29000 | 0.9 | 22.5 |

In the table 1, an item “No.” indicates each pattern of the examination. An item “element structure” indicates the number “N” of the vias 115. An item “L” indicates the length of the metal films 120. An item “W” indicates the width of the metal films 120. An item “resistance” indicates the resistance value of the metal films 120 measured between the wiring 110 and the wiring 130. An item “blowing current” indicates the current value measured when the metal film 120 is blown. An item “power” indicates the necessary power for the blowing.

Each of the patterns “No. 1” and “No. 2” has a configuration of the electric fuse according to the first embodiment in which the number of the vias 115 is smaller than the number of the vias 125. In this configuration, the metal film 120 having the width W larger than the length L was used. On the other hand, each of the patterns “No. 3” to “No. 5” has a configuration thereof in which the number of the vias 115 is equal to the number of the vias 125. In the pattern “No. 3”, the metal film 120 having the width W smaller than the length L was used. In the pattern “No. 4”, the metal film 120 having the width W equal to the length L was used. In the pattern “No. 5”, the metal film 120 having the width W smaller than the length L was used.

In the pattern “No. 1”, the number of the vias 115 is “N=1”. In the pattern “No. 2”, the number of the vias 115 is “N=3”. In the pattern “No. 3”, the numbers of the vias 115 and the vias 125 are “N=3×20”. In the pattern “No. 4”, the numbers of the vias 115 and the vias 125 are “N=3×10”. In the pattern “No. 5”, the numbers of the vias 115 and the vias 125 are “N=3”.

The following findings have been revealed from the above-described examination. When the area of the contact surface between the metal film 120 and the via 115 connected to the wiring 110 is smaller than the area of the contact surface between the metal film 120 and the via 125 connected to the wiring 130, the electric current can concentrate on the via 115 to be blown. In this manner, the blowing current flowing in the electric fuse 100 can be reduced. When the width W of the metal film 120 is large, the heat dissipation can be suppressed, and the blowing efficiency on the electric fuse 100 can be improved. In this case, the heat dissipation to outside can be suppressed when the via 115 is arranged near the center of the metal film 120 in the width direction. When the width W of the metal film 120 is small, the resistance of the metal film 120 is increased, and the necessary power for the blowing of the electric fuse 100 is increased. When the length L of the metal film 120 is small, the heat dissipation from the metal film 120 is easily caused, and the blowing current of the electric fuse 100 is increased.

When the number of the vias 125 connected to the wiring 130 is larger than the number of the vias 15 connected to the wiring 110, the entire resistance of the elements including the via 115 and the via 125 can be decreased. By the decrease in the entire resistance of the elements, the necessary power for the blowing can be decreased. When both the number of the vias 115 connected to the wiring 110 and the number of the vias 125 connected to the wiring 130 are small as seen in the example of the pattern “No. 5”, the entire resistance of the elements is increased. When the number of the vias 125 connected to the wiring 130 is larger than the number of the vias 15 connected to the wiring 110, the part of the metal film 120, the part being connected to the via 115, can be effectively blown while the entire resistance of the elements is decreased.

### Second Embodiment

Next, a second embodiment will be explained. FIG. 10 is a plan view showing an electric fuse included in a semiconductor device according to the second embodiment. The semiconductor device according to the second embodiment includes an electric fuse 300 in addition to the electric fuse 100. The electric fuse 300 includes a wiring 310, the metal film 120 and the wiring 130. In the second embodiment, the electric fuse 100 and the electric fuse 300 share the metal film 120 and the wiring 130.

In the second embodiment, the wiring 110 is connected to a first end of the metal film 120 through the via 115. Near the center of the metal film 120 in the longitudinal direction, the wiring 130 is connected to the metal film 120 through the via 125. The wiring 310 is connected to is connected to a second end of the metal film 120 through a via 315, the second end being opposite to the first end. The wiring 310 is also referred to as third wiring. The via 315 is also referred to as third via. Note that the number of the vias 135 is not limited to 1, and a plurality of vias 135 may be formed. In this case, the number of the plurality of vias 135 is smaller than the number of the vias 125.

The wiring 310 is made of a metal such as aluminum, copper, aluminum copper or the like. The wiring 310 may be formed to be upper or lower than the metal film 120. The via 315 is made of, for example, tungsten. A metal such as barrier metal may be formed at a boundary between the metal film 120 and the via 315.

A disconnect transistor is coupled to the wiring 130. At the time of the fuse disconnection, the disconnect transistor is turned ON, thereby making a flow of the blowing current from the wiring 310 to the metal film 120. The part of the metal film 120, the part being connected to the via 315, configures a blowing portion 321.

FIG. 11 is a circuit diagram showing an equivalent circuit of the electric fuses 100 and 300. The metal film 120 includes the blowing portion 121, the resistor portion 122, the blowing portion 321 and a resistor portion 322. The wiring 110 is connected to, for example, the power supply voltage Vd1. The wiring 310 is connected to, for example, a power supply voltage Vd2. The wiring 130 is coupled to the disconnect transistor 140. A source of the disconnect transistor 140 is coupled to a ground voltage, and a drain thereof is connected to the wiring 130. A gate of the disconnect transistor 140 is coupled to a terminal to which the control signal Vg for controlling the fuse disconnection is input. When at least either one of the electric fuses 100 and 300 is to be disconnected, the disconnect transistor 140 is controlled to be turned ON by the control signal Vg.

When the electric fuse 100 is to be disconnected, the power supply voltage Vd1 is supplied to the wiring 110. When the electric fuse 300 is to be disconnected, the power supply voltage Vd2 is supplied to the wiring 310. When the electric fuse 100 is not to be disconnected, the power supply voltage Vd1 is not supplied to the wiring 110, and the voltage of the wiring 110 is 0 V. Similarly, when the electric fuse 300 is not to be disconnected, the power supply voltage Vd2 is not supplied to the wiring 310, and the voltage of the wiring 310 is 0 V.

When the electric fuse 100 is to be disconnected, the disconnect transistor 140 is turned ON, thereby applying the power supply voltage Vd1 to the metal film 120 through the wiring 110, and supplying the blowing current from the wiring 110. The blowing current flows to the wiring 130 through the blowing portion 121 and the resistor portion 122. More specifically, the blowing current flows from the wiring 110 to the metal film 120 through the via 115, and flows to the wiring 130 through the plurality of vias 125. By the flow of the blowing current from the wiring 110 to the metal film 120, the blowing current particularly concentrates on the via 115, and the part of the metal film 120, the part being connected to the via 115, is heated by Joule heat. The part of the metal film 120, the part being connected to the via 115, is blown when exceeding certain temperature.

When the electric fuse 300 is to be disconnected, the disconnect transistor 140 is turned ON, thereby applying the power supply voltage Vd2 to the metal film 120 through the wiring 310, and supplying the blowing current from the wiring 310. The blowing current flows to the wiring 130 through the blowing portion 321 and the resistor portion 322. More specifically, the blowing current flows from the wiring 310 to the metal film 120 through the via 315, and flows to the wiring 130 through the plurality of vias 125. By the flow of the blowing current from the wiring 310 to the metal film 120, the blowing current particularly concentrates on the via 315, and the part of the metal film 120, the part being connected to the via 315, is heated by Joule heat. The connection part between the metal film 120 and the via 315 is blown when exceeding certain temperature.

### Effects

In the second embodiment, a first end of the metal film 120 that is the thin film resistor is connected to the wiring 110 through the via 115 configuring the blowing portion 121. A second end of the metal film 120 is connected to the wiring 310 through the via 315 configuring the blowing portion 321. Further, the center of the metal film 120 is connected to the wiring 130 through the plurality of vias 125. In the second embodiment, two electric fuses can be electrically connected to one metal film 120. In the second embodiment, two electric fuses that are connected to different circuits from each other are connected to one disconnect transistor 140, thereby making the disconnect transistor 140 sharable. Therefore, in the second embodiment, a circuit area of the semiconductor device can be reduced.

### Third Embodiment

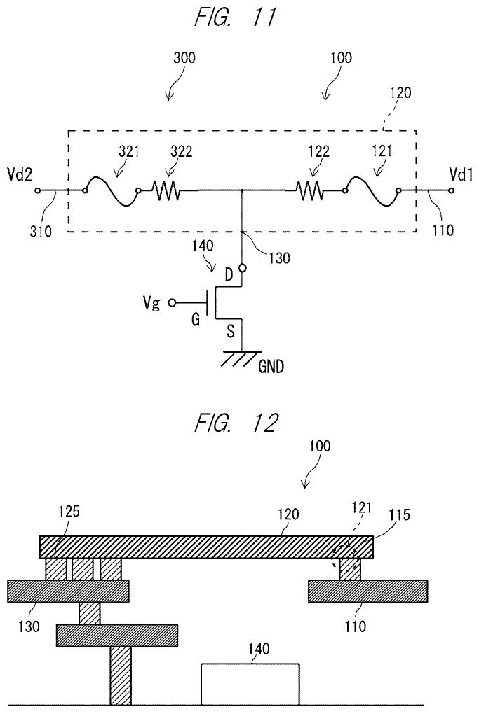

Subsequently, a third embodiment will be explained. FIG. 12 is a cross-sectional view showing a semiconductor device according to the third embodiment. In the third embodiment, the wiring 110, the metal film 120 and the wiring 130 configuring the electric fuse 100 are formed to be upper than the disconnect transistor 140. The semiconductor device according to the third embodiment may include the electric fuse 300 explained in the second embodiment in addition to the electric fuse 100.

The disconnect transistor 140 is formed on, for example, a semiconductor substrate. A plurality of wiring layers are formed on the semiconductor substrate. The plurality of wiring layers include a layer including the wiring 110 and the wiring 130 and a layer including the metal film 120. The metal film 120 and the disconnect transistor 140 may be formed to overlap each other in plan view.

### Effects

In the third embodiment, the wiring 110, the metal film 120 and the wiring 130 configuring the electric fuse 100 are farther from the semiconductor substrate, than in the case in which the electric fuse 100 is formed in the same layer as that of the disconnect transistor 140. Therefore, in the third embodiment, the influence of the blowing on the circuit on the semiconductor substrate at the time of the blowing of the blowing portion 121 can be reduced since the electric fuse 100 is far from the semiconductor substrate. In the third embodiment, the electric fuse 100 and the disconnect transistor 140 can be formed to overlap each other in plan view. In this case, the chip area can be made smaller than that in the case in which the electric fuse 100 and the disconnect transistor 140 are arranged side by side on the semiconductor substrate.

In the foregoing, the invention made by the present inventors has been concretely described based on the embodiments. However, it is needless to say that the present invention is not limited to the foregoing embodiments, and various modifications can be made within the scope of the present invention.

What is claimed is:

1. A semiconductor device comprising:
a metal film;
a first wiring connected to the metal film through one or more first vias;
a second wiring connected to the metal film through a plurality of second vias; and
a disconnect transistor coupled to the second wiring,
wherein an area of a contact surface, which is in contact with the metal film, of the one or more first vias is smaller than an area of a contact surface, which is in contact with the metal film, of the plurality of second vias, and
wherein the metal film configures an electric fuse element.

2. The semiconductor device according to claim 1,
wherein when a blowing current is flowed from the first wiring to the metal film by the disconnect transistor, a part of the metal film, the part being connected to the one or more first vias, is blown.

3. The semiconductor device according to claim 1,
wherein the metal film is made of silicon chromium or titanium nitride.

4. The semiconductor device according to claim 1,
wherein a width of the first wiring is smaller than a width of the second wiring.

5. The semiconductor device according to claim 1,
wherein the metal film is formed to be upper than the first wiring and the second wiring.

6. The semiconductor device according to claim 1,
wherein the metal film is formed to be lower than the first wiring and the second wiring.

7. The semiconductor device according to claim 1,
wherein the number of the one or more first vias is smaller than the number of the plurality of second vias.

8. The semiconductor device according to claim 1, further comprising
a third wiring connected to the metal film through one or more third vias,
wherein when a blowing current is flowed from the third wiring to the metal film by the disconnect transistor, a part of the metal film, the part being connected to the one or more third vias, is blown.

9. The semiconductor device according to claim 8,
wherein the first wiring is connected to a first end of the metal film through the one or more first vias,
wherein the third wiring is connected to a second end of the metal film through the one or more third vias, the second end being opposite to the first end, and
wherein the second wiring is connected to a middle part between the first end and the second end of the metal film through the plurality of second vias.

10. The semiconductor device according to claim 1,
wherein the disconnect transistor is formed on a substrate, and
wherein the first wiring, the second wiring and the metal film are formed to be upper than the disconnect transistor.

11. The semiconductor device according to claim 10,
wherein the metal film and the disconnect transistor are formed to overlap each other in plan view.

12. The semiconductor device according to claim 1,
wherein the metal film is formed into a rectangular shape, and
wherein a width of the metal film in a direction perpendicular to a direction extending from the one or more first vias to the plurality of second vias is constant.

13. The semiconductor device according to claim 1,
wherein a width of the metal film is larger than a width of the first wiring.
